(19) United States
(12) Patent Application Publication
(10) Pub. No.: US 2006/0220207 A1
(43) Pub. Date: Oct. 5, 2006

(54) Stacked semiconductor package

(75) Inventor: Toshitaka Akahoshi, Kyoto (JP)

Correspondence Address: STEPTOE & JOHNSON LLP, 1330 CONNECTICUT AVE., NW, WASHINGTON, DC, 20036, US

(73) Assignee: Matsushita Electric Industrial Co., Ltd., Kadoma-shi (JP)

(21) Appl. No.: 11/376,309

(22) Filed: Mar. 16, 2006

(30) Foreign Application Priority Data
Mar. 17, 2005 (JP) 2005-076172
Nov. 10, 2005 (JP) 2005-325496

(51) Int. Cl. H01L 23/02

(52) U.S. Cl. 257/686

(57) ABSTRACT

A metal pattern for heat dissipation is formed on the backside of a second semiconductor substrate, the metal pattern being in contact with a first semiconductor element mounted on a semiconductor device adjacent to the backside. Vias are formed on the peripheries of semiconductor substrates, the vias penetrating in the thickness direction to transmit heat. The vias and the metal pattern for heat dissipation are connected to each other on the backside of the semiconductor substrate. Solder balls disposed between the semiconductor devices transmit heat having been transmitted to the metal pattern of the semiconductor device to the vias of the semiconductor device adjacent to the backside of the semiconductor device having the metal pattern.

### FIELD OF THE INVENTION

The present invention relates to a stacked semiconductor package in which a plurality of semiconductor devices are stacked, each semiconductor device having a semiconductor element mounted thereon.

### BACKGROUND OF THE INVENTION

As portable information equipment or the like is reduced in size and weight, semiconductor device packages with a high density, a small size, and a small thickness are demanded. In response to the needs, stacked semiconductor packages have been developed with semiconductor devices stacked in multiple stages. In such stacked semiconductor packages, however, the semiconductor devices are densely stacked, so that heat generated from semiconductor elements is likely to be retained in the semiconductor devices. In order to solve this problem, Japanese Patent Laid-Open No. 2000-12765 proposes a heat dissipation structure which dissipates heat generated from semiconductor elements to the outside to stabilize the operations of the semiconductor elements.

FIG. 8 is a sectional view showing a conventional stacked semiconductor package having such a heat dissipation structure. A first semiconductor element 101 is mounted on a first semiconductor substrate 102 by flip-chip connection. A second semiconductor element 103 is similarly mounted on a second semiconductor substrate 104 by flip-chip connection. Further, the first semiconductor substrate 102 and the second semiconductor substrate 104 are connected and the second semiconductor substrate 104 and a motherboard 105 are connected via solder balls 106 disposed between the substrates 102, 104 and the motherboard 105. Moreover, a plurality of heat dissipating vias 107 are formed in the first semiconductor substrate 102, the second semiconductor substrate 104, and the motherboard 105 such that heat is easily dissipated through the substrates 102 and 104 and the motherboard 105 to the opposite sides of the substrates 102 and 104 and the motherboard 105. The vias 17 have inner surfaces plated with a metal or the vias 17 are filled with a heat transfer member made of a resin material or the like containing a metal or ceramic.

However, in the conventional stacked semiconductor package, the vias 107 acting as heat dissipating paths are placed at the center such that the vias 107 in the semiconductor substrates 102 and 104 face the semiconductor elements 101 and 103. Thus, when routing wires for connecting internal electrode terminals of the semiconductor substrates 102 and 104, which are flip-chip connected to the electrodes of the semiconductor elements 101 and 103, to external electrode terminals disposed on the opposite side from the surfaces where the semiconductor elements 101 and 103 are mounted, the vias 107 interfere with the wires and the wires are less flexibly routed, so that a pin layout requested by the customer (client) may not be obtained. Consequently, the semiconductor elements 101 and 103 may not be stacked.

### DISCLOSURE OF THE INVENTION

The present invention is designed to solve the problem. An object of the present invention is to provide a stacked semiconductor package by which high heat dissipation efficiency is obtained and flexibility in routing wires is not reduced while a plurality of semiconductor devices having semiconductor elements mounted thereon are stacked.

In order to solve the conventional problem, the stacked semiconductor package of the present invention is configured as follows:

Provided by the present invention is a stacked semiconductor package, in which semiconductor devices each having a semiconductor element mounted on a surface of a semiconductor substrate are stacked in a plurality of stages, the semiconductor package comprising: a metal pattern formed for heat dissipation on the backside of the semiconductor substrate, the metal pattern being in contact with a structure covering the semiconductor element mounted on the semiconductor device adjacent to the backside, vias formed on the periphery of the semiconductor substrate, the vias penetrating in the thickness direction to transmit heat, the vias and the metal pattern for heat dissipation being connected to each other on the backside of the semiconductor substrate, and solder balls disposed between the semiconductor devices, the solder balls transmitting heat having been transmitted to the metal pattern of the semiconductor device to the vias of the semiconductor device adjacent to the backside of the semiconductor device having the metal pattern.

According to this configuration, heat generated on the semiconductor element is transmitted to the metal pattern in contact with the structure covering the semiconductor element, and heat on the metal pattern is transmitted to the vias connected to the metal pattern and dissipated therefrom. Further, the heat transmitted to the metal pattern of the semiconductor device is transmitted through the solder balls to the vias of the semiconductor device adjacent to the backside of the semiconductor device having the metal pattern. Thus, heat generated on the semiconductor element can be dissipated in a preferable manner. Moreover, according to this configuration, since the vias acting as heat dissipating paths are disposed on the periphery of the semiconductor substrate, when routing connecting wires for connecting external electrode terminals and the internal electrode terminals of the semiconductor substrate connected to the semiconductor element, the vias hardly interfere with the wires and high flexibility can be kept for routing the connecting wires. Therefore, a pin layout requested by the customer can be freely implemented and the stacked semiconductor package can be stably provided with ease.

Another stacked semiconductor package of the present invention is a stacked semiconductor package, in which semiconductor devices each having a semiconductor element flip-chip mounted on a surface of a semiconductor substrate are stacked in a plurality of stages, the semiconductor package comprising: a metal pattern formed for heat dissipation on the backside of the semiconductor substrate, the metal pattern being in contact with the semiconductor element mounted on the semiconductor device adjacent to the backside, vias formed on the periphery of the semiconductor substrate, the vias penetrating in the thickness direction to transmit heat, the vias and the metal pattern for heat dissipation being connected to each other on the backside of the semiconductor substrate, and solder balls disposed between the semiconductor devices, the solder balls transmitting heat having been transmitted to the metal pattern of the semiconductor device to the vias of the semiconductor device adjacent to the backside of the semiconductor device having the metal pattern.

According to this configuration, heat generated on the semiconductor element is transmitted to the metal pattern in contact with the semiconductor element, and heat on the metal pattern is transmitted to the vias connected to the metal pattern and dissipated therefrom. Further, the heat transmitted to the metal pattern of the semiconductor device is transmitted through the solder balls to the vias of the semiconductor device adjacent to the backside of the semiconductor device having the metal pattern. Thus, heat generated on the semiconductor element can be dissipated in a preferable manner. Moreover, according to this configuration, since the vias acting as heat dissipating paths are disposed on the periphery of the semiconductor substrate, when routing connecting wires for connecting external electrode terminals and the internal electrode terminals of the semiconductor substrate connected to the semiconductor element, the vias hardly interfere with the connecting wires and high flexibility can be kept for routing the connecting wires. Therefore, a pin layout requested by the customer can be freely implemented and the stacked semiconductor package can be stably provided with ease.

Further, the stacked semiconductor package of the present invention is characterized in that the metal pattern for heat dissipation on the backside of the semiconductor substrate of the semiconductor device and the semiconductor element mounted on the semiconductor device adjacent to the backside of the semiconductor device are bonded to each other with an adhesive having a high heat transfer coefficient.

According to this configuration, heat on the semiconductor element is preferably transmitted to the metal pattern for heat dissipation through the adhesive having a high heat transfer coefficient, thereby more preferably dissipating heat generated on the semiconductor element.

Further, the stacked semiconductor package of the present invention is characterized in that the metal pattern for heat dissipation is connected to the solder balls and vias used for ground electrodes.

According to this configuration, it is possible to stabilize the voltage on the backside of the semiconductor element mounted on the semiconductor substrate, thereby easily stacking an analog IC or the like which requires back bias.

Still further, the stacked semiconductor package of the present invention is characterized in that the semiconductor element has electrodes arranged in a lattice form over a surface of the semiconductor element.

### BRIEF DESCRIPTION OF THE DRAWINGS

FIG. 1A is a sectional view showing a stacked semiconductor package according to Embodiment 1 of the present invention;

FIG. 1B is a plan view taken from the below (bottom) of a semiconductor substrate used for the stacked semiconductor package;

FIG. 2 is a sectional view showing a modification of the stacked semiconductor package according to Embodiment 1 of the present invention;

FIG. 3A is a sectional view showing a stacked semiconductor package according to Embodiment 2 of the present invention;

FIG. 3B is a plan view taken from the below (bottom) of a semiconductor substrate used for the stacked semiconductor package;

FIG. 4A is a sectional view showing a stacked semiconductor package according to Embodiment 3 of the present invention;

FIG. 4B is a plan view taken from the below (bottom) of a semiconductor substrate used for the stacked semiconductor package;

FIG. 5A is a sectional view showing a stacked semiconductor package according to Embodiment 4 of the present invention;

FIG. 5B is a plan view taken from the below (bottom) of a semiconductor substrate used for the stacked semiconductor package;

FIG. 6 is a sectional view showing a stacked semiconductor package according to Embodiment 5 of the present invention;

FIG. 7A is a plan view taken from the below of a semiconductor element used for the stacked semiconductor package;

FIG. 7B is a plan view taken from the below (bottom) of a semiconductor substrate used for the stacked semiconductor package; and

FIG. 8 is a sectional view showing a conventional stacked semiconductor package.

### DESCRIPTION OF THE EMBODIMENTS

The following will describe a heat dissipation structure of a stacked semiconductor package according to embodiments of the present invention with reference to the accompanying drawings.

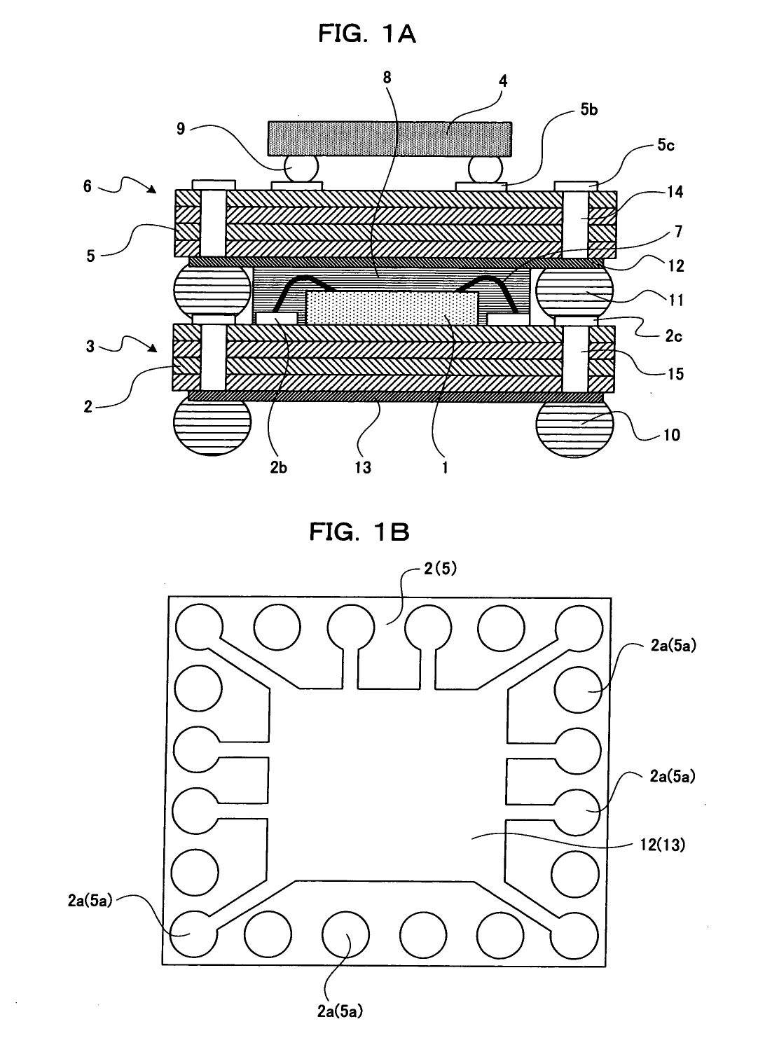

Referring to FIGS. 1A and 1B, the following will discuss the stacked semiconductor package according to Embodiment 1 of the present invention. FIG. 1A is a sectional view showing the stacked semiconductor package. FIG. 1B is a plan view taken from the below (bottom) of a semiconductor substrate used for the stacked semiconductor package.

As shown in FIG. 1A, the stacked semiconductor package is configured such that a second semiconductor device 6 has a second semiconductor element 4 mounted on a second semiconductor substrate 5 and the second semiconductor device 6 is stacked on a first semiconductor device 3 having a first semiconductor element 1 mounted on a first semiconductor substrate 2.

As shown in FIG. 1B, a plurality of external electrode terminals 2a are formed on the periphery of the bottom of the first semiconductor substrate 2. As shown in FIG. 1A, a plurality of first electrodes (internal electrode terminals) 2b are formed around the center of the top surface of the first semiconductor substrate 2 and a plurality of second electrodes 2c are formed on the periphery of the top surface of the first semiconductor substrate 2. Further, the first semiconductor element 1 is mounted faceup on the top surface of the first semiconductor substrate 2. The first electrodes 2b and the first semiconductor element 1 are electrically connected via wires 7 made of a material such as Au. The first semiconductor element 1 and the wires 7 are molded with sealing resin 8. Moreover, the first electrodes 2b serving as the internal electrode terminals of the first semiconductor substrate 2 and the external electrode terminals 2a of the first semiconductor substrate 2 are electrically connected via connecting wires (not shown) provided on the first semiconductor substrate 2.

Similarly, as shown in FIG. 1B, a plurality of external electrode terminals 5a are formed on the periphery of the bottom of the second semiconductor substrate 5. As shown in FIG. 1A, a plurality of first electrodes (internal electrode terminals) 5b are formed around the center of the top surface of the second semiconductor substrate 5 and a plurality of second electrodes 5c are formed on the periphery of the top surface of the second semiconductor substrate 5. The second semiconductor element 4 and the first electrodes 5b of the second semiconductor substrate 5 are flip-chip connected facedown via protruding electrodes 9 such as solder balls. The second semiconductor element 4 may be flip-chip mounted facedown, or the second semiconductor element 4 may be mounted faceup and covered with the sealing resin. The way to mount the second semiconductor element 4 is not particularly limited.

Moreover, the first electrodes 5b serving as the internal electrode terminals of the second semiconductor substrate 5 and the external electrode terminals 5a of the second semiconductor substrate 5 are electrically connected via connecting wires (not shown) provided on the second semiconductor substrate 5.

Solder balls 10 for electrical connection with a motherboard (not shown) are provided on the external electrode terminals 2a of the first semiconductor substrate 2.

Further, the plurality of second electrodes 2c provided on the periphery of the top surface of the first semiconductor substrate 2 and the external electrode terminals 5a provided on the periphery of the bottom of the second semiconductor substrate 5 are connected via solder balls 11.

A metal pattern 12 for heat dissipation is formed on the backside of the second semiconductor substrate 5. The metal pattern 12 is in contact with the sealing resin 8 covering the first semiconductor element 1.

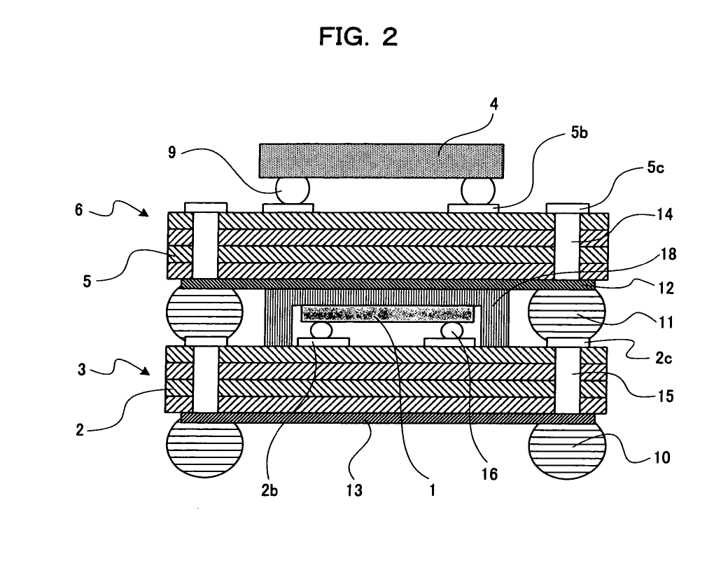

The present invention is not limited to this configuration. For example, as shown in FIG. 2, the first semiconductor element 1 may be flip-chip mounted facedown and a metallic radiator plate 18 may be provided over the first semiconductor element 1. In this case, the metal pattern 12 formed for heat dissipation on the backside of a second semiconductor substrate 5 is in contact with the metallic radiator plate 18.

The radiator plate 18 is made of, for example, chromium-plated copper but the material is not particularly limited.

The metal pattern 12 is physically (thermally) and electrically connected to some of the external electrode terminals 5a formed on the backside of the second semiconductor substrate 5 shown in FIG. 1B. During the formation of the second semiconductor substrate 5, the metal pattern 12 is formed concurrently with the external electrode terminals 5a formed on the same backside. For example, the metal pattern 12 is formed by nickel plating or gold plating on a metallic material such as tungsten and molybdenum. In this embodiment, a metal pattern 13 having a similar configuration is formed on the backside of the first semiconductor substrate 2. The metal pattern 13 is physically (thermally) and electrically connected to some of the external electrode terminals 2a formed on the backside of the first semiconductor substrate 2 shown in FIG. 1B. The configuration is not limited to the above.

As shown in FIG. 1A, a plurality of vias 14 and 15 are formed on the peripheries of the semiconductor substrates 2 and 5 so as to penetrate from the top surfaces to the backsides of the substrates. Through the vias 14 provided in the second semiconductor substrate 5, the second electrodes 5c provided on the periphery of the top surface of the second semiconductor substrate 5 and the metal pattern 12 provided on the backside of the second semiconductor substrate 5 are physically (thermally) and electrically connected to each other. Further, through the vias 15 provided in the first semiconductor substrate 2, the second electrodes 2c provided on the periphery of the top surface of the first semiconductor substrate 2 and the metal pattern 12 provided on the backside of the second semiconductor substrate 2 are physically (thermally) and electrically connected to each other. The vias 14 and 15 have inner surfaces plated with a metal, or the vias 14 and 15 are filled with a metal or a resin material containing a metal or ceramic.

In this configuration, the second semiconductor device 6 is stacked on the first semiconductor device 3. The metal pattern 12 provided on the backside of the second semiconductor substrate 5 is in contact with the sealing resin 8 and the radiator plate 18 which are structures covering the first semiconductor element 1 of the first semiconductor device 3. Thus, heat generated on the first semiconductor element 1 is transmitted to the metal pattern 12 through the sealing resin 8 and the radiator plate 18, heat on the metal pattern 12 is transmitted from the external electrode terminals 5a connected to the metal pattern 12 to the vias 14 of the second semiconductor substrate 5 connected above the external electrode terminals 5a, and then the heat is transmitted to the solder balls 11 connected below the external electrode terminals 5a, and the second electrodes 2c and the vias 15 of the first semiconductor substrate 2. Further, the heat is also transmitted to the metal pattern 13 and the solder balls 10 through the external electrode terminals 2a of the first semiconductor substrate 2 connected to the vias 15. Therefore, heat generated on the first semiconductor element 1 is preferably transmitted and dissipated through the metal pattern 12, the external electrode terminals 5a, the vias 14, the solder balls 11, the second electrodes 2c, the vias 15, the external electrode terminals 2a, the metal pattern 13, and the solder balls 10, thereby keeping quite high heat dissipation efficiency.

Moreover, the vias 14 and 15 acting as heat dissipating paths are disposed on the peripheries of the first and second semiconductor substrates 2 and 5 instead of the centers of the substrates. Thus, when routing the connecting wires for connecting the external electrode terminals 2a and 5a and the first electrodes 2b and 5b acting as the internal electrode terminals of the semiconductor substrates 2 and 5, which are connected to the electrodes of the semiconductor elements 1 and 4 via the wires 7 and the protruding electrodes 16 and 9, the vias 14 and 15 hardly interfere with the connecting wires, routing is performed with high flexibility, and a pin layout requested by the customer (client) is freely implemented. Therefore, even the stacked semiconductor devices 3 and 6 (semiconductor elements 1 and 4) do not cause any problems. Such a stacked semiconductor package can be stably provided with ease.

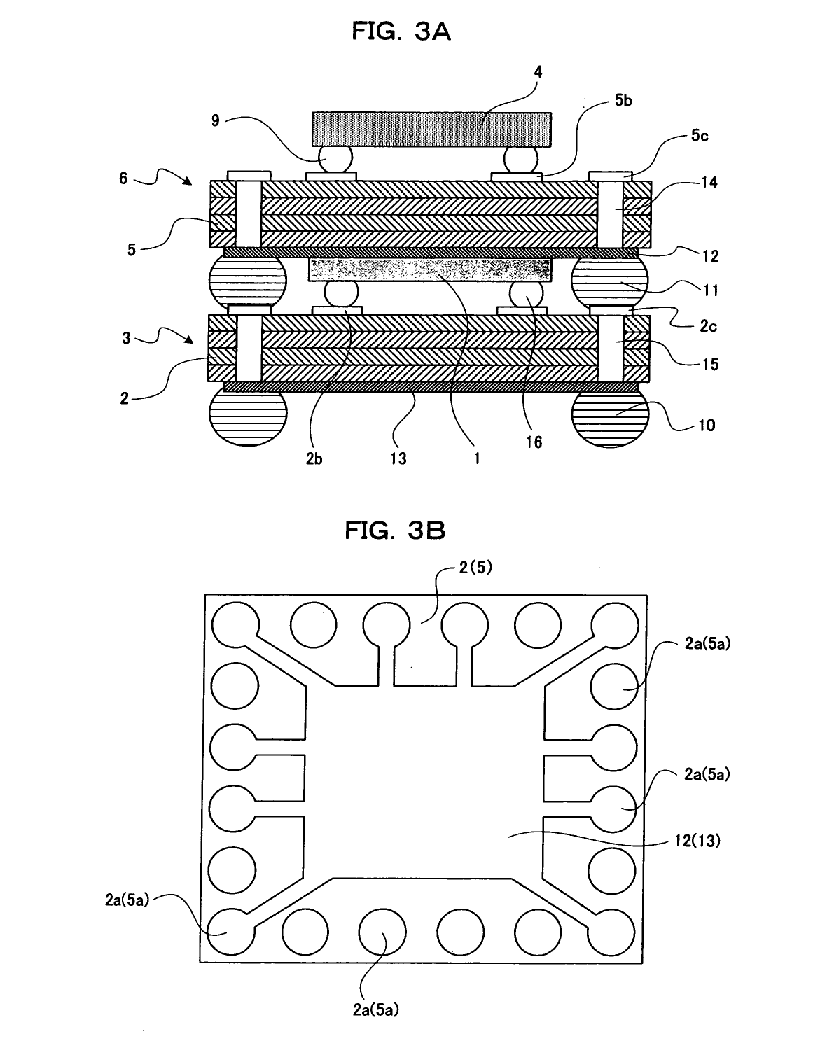

Referring to FIGS. 3A and 3B, the following will discuss a stacked semiconductor package according to Embodiment 2 of the present invention. FIG. 3A is a sectional view showing the stacked semiconductor package. FIG. 3B is a plan view taken from the below (bottom) of a semiconductor substrate used for the stacked semiconductor package.

As shown in FIG. 3A, the stacked semiconductor package is configured such that a second semiconductor device 6 has a second semiconductor element 4 mounted on a second semiconductor substrate 5 and the second semiconductor device 6 is stacked on a first semiconductor device 3 having a first semiconductor element 1 mounted on a first semiconductor substrate 2.

As shown in FIG. 3B, a plurality of external electrode terminals 2a are formed on the periphery of the bottom of the first semiconductor substrate 2. As shown in FIG. 3A, a plurality of first electrodes (internal electrode terminals) 2b are formed around the center of the top surface of the first semiconductor substrate 2 and a plurality of second electrodes 2c are formed on the periphery of the top surface of the first semiconductor substrate 2. The first semiconductor element 1 and the first electrodes 2b of the first semiconductor substrate 2 are flip-chip connected facedown via protruding electrodes 16 such as solder balls. Moreover, the first electrodes 2b acting as the internal electrode terminals of the first semiconductor substrate 2 and the external electrode terminals 2a of the first semiconductor substrate 2 are electrically connected via connecting wires (not shown) provided on the first semiconductor substrate 2.

Similarly, as shown in FIG. 3B, a plurality of external electrode terminals 5a are formed on the periphery of the bottom of the second semiconductor substrate 5. As shown in FIG. 3A, a plurality of first electrodes (internal electrode terminals) 5b are formed around the center of the top surface of the second semiconductor substrate 5 and a plurality of second electrodes 5c are formed on the periphery of the top surface of the second semiconductor substrate 5. The second semiconductor element 4 and the first electrodes 5b of the second semiconductor substrate 5 are flip-chip connected facedown via protruding electrodes 9 such as solder balls. Moreover, the first electrodes 5b acting as the internal electrode terminals of the second semiconductor substrate 5 and the external electrode terminals 5a of the second semiconductor substrate 5 are electrically connected via connecting wires (not shown) provided on the second semiconductor substrate 5.

Solder balls 10 for electrical connection with a motherboard (not shown) are provided on the external electrode terminals 2a of the first semiconductor substrate 2.

Further, the plurality of second electrodes 2c provided on the periphery of the top surface of the first semiconductor substrate 2 and the external electrode terminals 5a provided on the periphery of the bottom of the second semiconductor substrate 5 are connected via solder balls 11.

A metal pattern 12 for heat dissipation is formed on the backside of the second semiconductor substrate 5. The metal pattern 12 is in contact with the backside of the first semiconductor element 4. The metal pattern 12 is physically (thermally) and electrically connected to some of the external electrode terminals 5a formed on the backside of the second semiconductor substrate 5 shown in FIG. 3B. During the formation of the second semiconductor substrate 5, the metal pattern 12 is formed concurrently with the external electrode terminals 5a formed on the same backside. For example, the metal pattern 12 is formed by nickel plating or gold plating on a metallic material such as tungsten and molybdenum. In this embodiment, a metal pattern 13 having a similar configuration is formed on the backside of the first semiconductor substrate 2. The metal pattern 13 is physically (thermally) and electrically connected to some of the external electrode terminals 2a formed on the backside of the first semiconductor substrate 2 shown in FIG. 3B. The configuration is not limited to the above.

As shown in FIG. 3A, a plurality of vias 14 and 15 are formed on the peripheries of the semiconductor substrates 2 and 5 so as to penetrate from the top surfaces to the backsides of the substrates. Through the vias 14 provided in the second semiconductor substrate 5, the second electrodes 5c provided on the periphery of the top surface of the second semiconductor substrate 5 and the metal pattern 12 provided on the backside of the second semiconductor substrate 5 are physically (thermally) and electrically connected to each other. Further, through the vias 15 provided in the first semiconductor substrate 2, the second electrodes 2c provided on the periphery of the top surface of the first semiconductor substrate 2 and the metal pattern 13 provided on the backside of the second semiconductor substrate 2 are physically (thermally) and electrically connected to each other. The vias 14 and 15 have inner surfaces plated with a metal, or the vias 14 and 15 are filled with a metal or a resin material containing a metal or ceramic.

In this configuration, the second semiconductor device 6 is stacked on the first semiconductor device 3. The metal pattern 12 provided on the backside of the second semiconductor substrate 5 is in contact with the first semiconductor element 1 of the first semiconductor device 3. Thus, heat generated on the first semiconductor element 1 is transmitted to the metal pattern 12 and heat on the metal pattern 12 is transmitted from the external electrode terminals 5a connected to the metal pattern 12 to the vias 14 of the second semiconductor substrate 5 connected above the external electrode terminals 5a, and then the heat is transmitted to the solder balls 11 connected below the external electrode terminals 5a, and the second electrodes 2c and the vias 15 of the first semiconductor substrate 2. Then, the heat is transmitted to the metal pattern 13 and the solder balls 10 through the external electrode terminals 2a of the first semiconductor substrate 2 connected to the vias 15. Therefore, heat generated on the first semiconductor element 1 is preferably transmitted and dissipated through the metal pattern 12, the external electrode terminals 5a, the vias 14, the solder balls 11, the second electrodes 2c, the vias 15, the external electrode terminals 2a, the metal pattern 13, and the solder balls 10, thereby keeping quite high heat dissipation efficiency.

Moreover, the vias 14 and 15 acting as heat dissipating paths are disposed on the peripheries of the first and second semiconductor substrates 2 and 5 instead of the centers of the substrates. Thus, when routing the connecting wires for connecting the external electrode terminals 2a and 5a and the first electrodes 2b and 5b acting as the internal electrode terminals of the semiconductor substrates 2 and 5, which are connected to the electrodes of the semiconductor elements 1 and 4 via the protruding electrodes 16 and 9, the vias 14 and 15 hardly interfere with the connecting wires, routing is performed with high flexibility, and a pin layout requested by the customer (client) is freely implemented. Therefore, even the stacked semiconductor devices 3 and 6 (semiconductor elements 1 and 4) do not cause any problems. Such a stacked semiconductor package can be stably provided with ease.

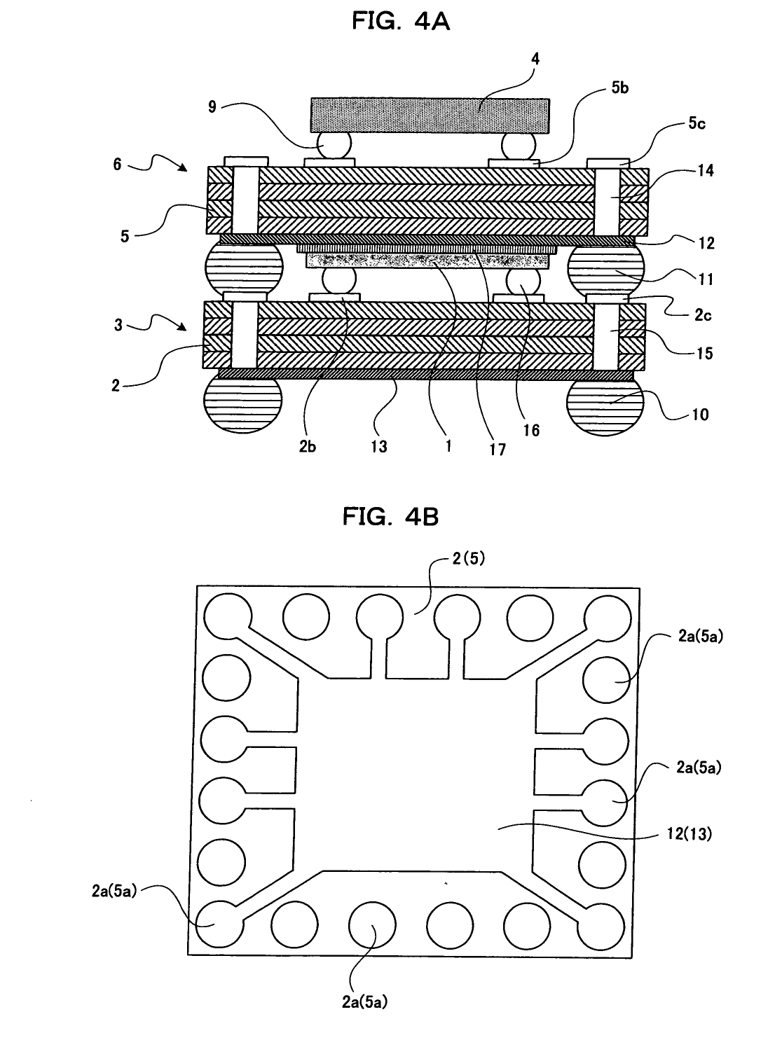

Referring to FIGS. 4A and 4B, the following will discuss a stacked semiconductor package according to Embodiment 3 of the present invention. FIG. 4A is a sectional view showing the stacked semiconductor package. FIG. 4B is a plan view taken from the below (bottom) of a semiconductor substrate used for the stacked semiconductor package. The constituent elements having the same functions as those of the stacked semiconductor package of Embodiment 2 are indicated by the same reference numerals and the explanation thereof is omitted.

As shown in FIG. 4A, in this stacked semiconductor package, heat is preferably transmitted by a heat dissipating metal pattern 12 provided on the backside of a second semiconductor substrate 5 of a second semiconductor device 6 and a semiconductor element 1 mounted on a first semiconductor device 3 adjacent to the backside of the second semiconductor device 6. In other words, the metal pattern 12 and the first semiconductor element 1 are electrically bonded to each other with conductive adhesive 17 having a high heat transfer coefficient.

The conductive adhesive 17 is, for example, a binder of epoxy resin and a conductor filler of an Ag—Pd alloy in consideration of reliability and thermal stress. The conductive adhesive 17 may be either paste or a sheet.

According to this configuration, the same operation/working effect as Embodiments 1 and 2 can be obtained. Moreover, heat on the first semiconductor element 1 is preferably transmitted to the heat dissipating metal pattern 12 through the conductive adhesive 17 having a high heat transfer coefficient, and thus heat generated on the first semiconductor element 1 is dissipated in a more preferable manner.

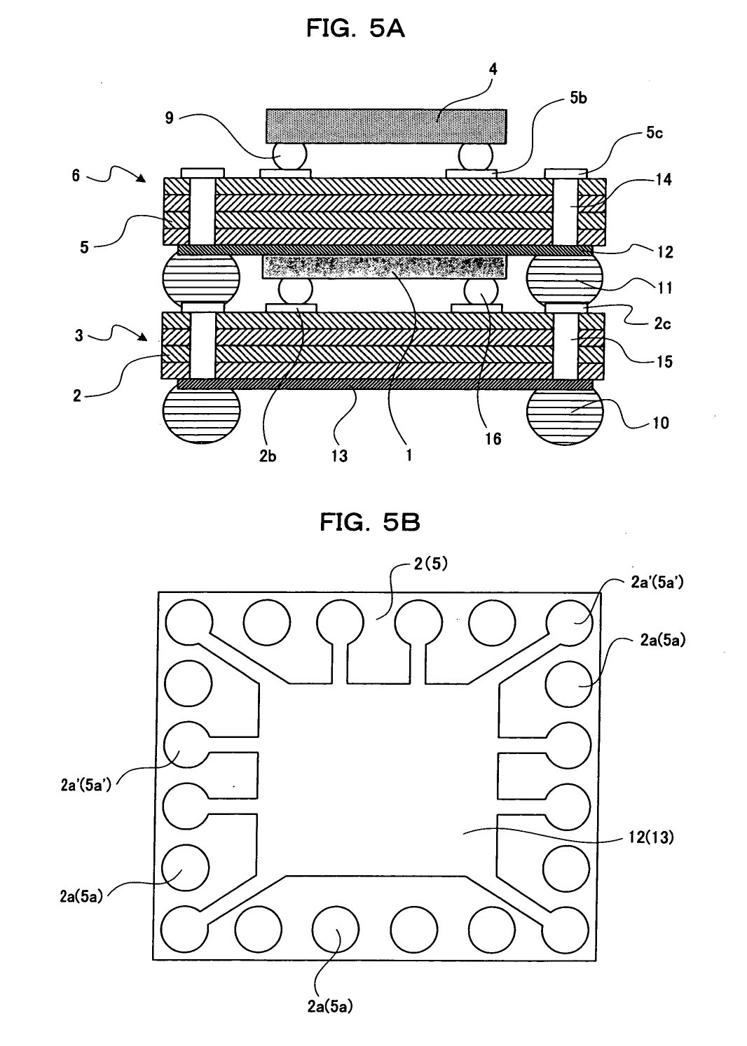

Referring to FIGS. 5A and 5B, the following will discuss a stacked semiconductor package according to Embodiment 4 of the present invention. FIG. 5A is a sectional view showing the stacked semiconductor package. FIG. 5B is a plan view taken from the below (bottom) of a semiconductor substrate used for the stacked semiconductor package. The constituent elements having the same functions as those of the stacked semiconductor package of Embodiment 2 are indicated by the same reference numerals and the explanation thereof is omitted.

As shown in FIG. 5B, in this stacked semiconductor package, a metal pattern 12 formed on the backside of a second semiconductor substrate 5 is connected only to ground electrodes 5a′ out of external electrode terminals 5a disposed on the periphery of the bottom of the second semiconductor substrate 5. The ground electrodes 5a′ are connected to vias 14 used for ground electrodes and solder balls 11 used for ground electrodes.

According to this configuration, the same operation/working effects as Embodiments 1 and 2 can be obtained. Moreover, since the metal pattern 12 is connected only to the ground electrodes 5a′, it is possible to stabilize voltage on the backside of a second semiconductor element 4 mounted on the second semiconductor substrate 5, thereby easily stacking an analog IC or the like which requires back bias.

In this embodiment, a metal pattern 13 formed on the backside of the first semiconductor substrate 2 is also connected only to ground electrodes 2a′ out of external electrode terminals 2a disposed on the periphery of the bottom of the first semiconductor substrate 2.

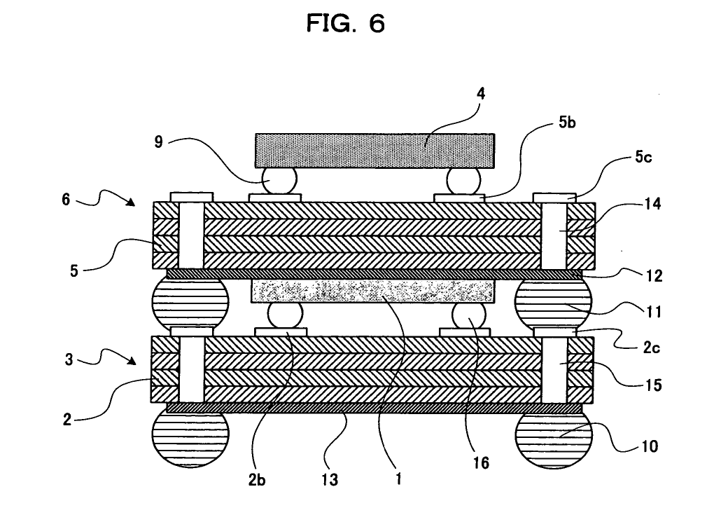

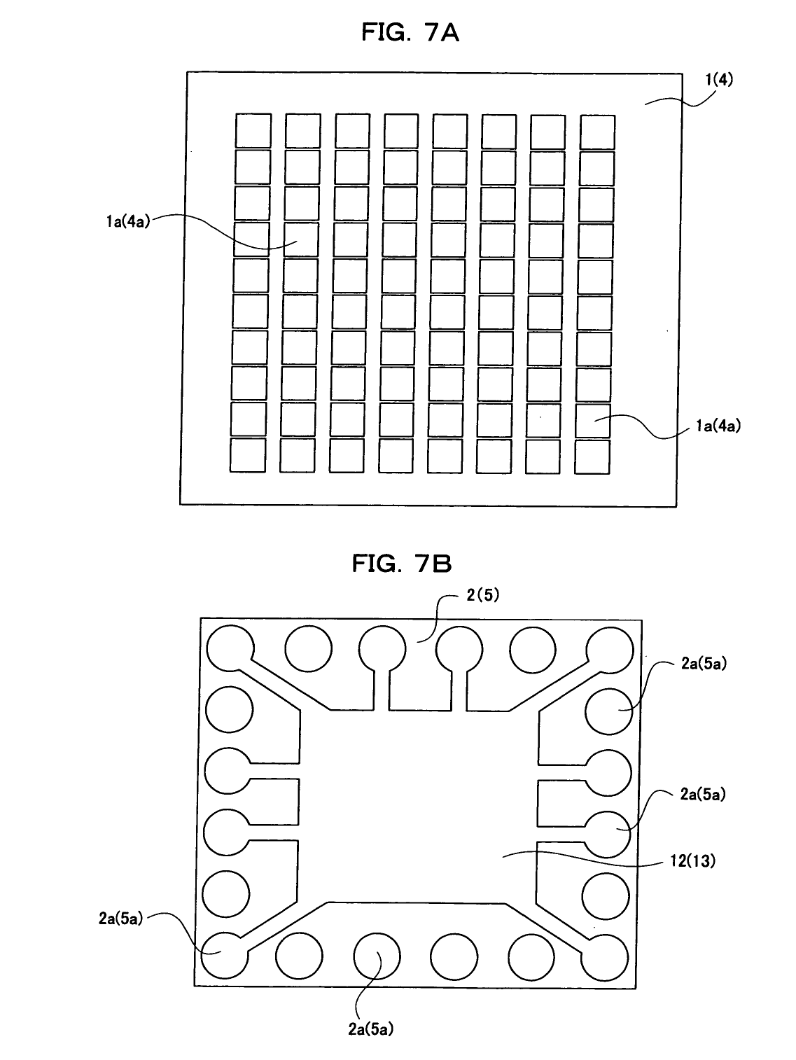

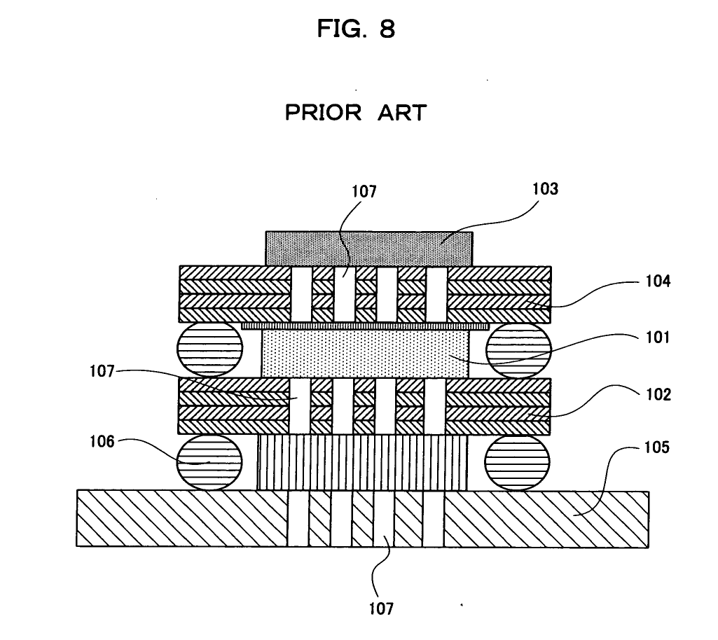

Referring to FIGS. 6 and 7A and 7B, the following will discuss a stacked semiconductor package according to Embodiment 5 of the present invention. FIG. 6 is a sectional view showing the stacked semiconductor package. FIG. 7A is a plan view taken from the below of a semiconductor element used for the stacked semiconductor package. FIG. 7B is a plan view taken from the below (bottom) of a semiconductor substrate used for the stacked semiconductor package. The constituent elements having the same functions as those of the stacked semiconductor package of Embodiment 2 are indicated by the same reference numerals and the explanation thereof is omitted.

As shown in FIG. 7A, in this stacked semiconductor package, electrodes 1a of a first semiconductor element 1 are arranged in a lattice form over a surface of the semiconductor element. In response to the electrodes 1a, first electrodes 2b acting as the internal electrode terminals of a first semiconductor substrate 2 are arranged in a lattice form, and protruding electrodes 16 such as solder balls for connecting the electrodes 2b are also arranged in a lattice form.

Further, electrodes 4a of a second semiconductor element 4 are similarly arranged in a lattice form over the surface of the semiconductor element. In response to the electrodes 4a, first electrodes 5b acting as the internal electrode terminals of a second semiconductor substrate 5 are arranged in a lattice form, and protruding electrodes 9 such as solder balls for connecting the electrodes 5b are also arranged in a lattice form.

According to this configuration, the same operation/working effect as Embodiment 1 can be obtained. Moreover, vias 14 and 15 acting as heat dissipating paths are disposed on the peripheries of the first and second semiconductor substrates 2 and 5. Thus, the electrodes 1a and 4a of the semiconductor elements 1 and 4 are arranged in a lattice form over the surfaces of the semiconductor elements. Accordingly, the protruding electrodes 16 and 9 and the first electrodes 2b and 5b acting as the internal electrode terminals of the semiconductor substrates 2 and 5 are arranged in a lattice form. Even in this case, when routing connecting wires for connecting external electrode terminals 2a and 5a and the first electrodes 2b and 5b acting as the internal electrode terminals of the semiconductor substrates 2 and 5, the vias 14 and 15 hardly interfere with the connecting wires, routing is performed with high flexibility, and a pin layout requested by the customer (client) is freely implemented. Therefore, even the stacked semiconductor devices 3 and 6 (semiconductor elements 1 and 4) do not cause any problems. Such a stacked semiconductor package can be stably provided with ease.

Embodiments 1 to 5 described the stacked semiconductor packages of two stages. The configuration of the package is not particularly limited. A similar heat dissipation structure is applicable to stacked semiconductor packages in which semiconductor devices are stacked in two or more stages, for example, in three or four stages.

What is claimed is:

1. A stacked semiconductor package, in which semiconductor devices each having a semiconductor element mounted on a surface of a semiconductor substrate are stacked in a plurality of stages,
the semiconductor package comprising:
a metal pattern formed for heat dissipation on a backside of the semiconductor substrate, the metal pattern being in contact with a structure covering the semiconductor element mounted on the semiconductor device adjacent to the backside;
vias formed on a periphery of the semiconductor substrate, the vias penetrating in a thickness direction to transmit heat, the vias and the metal pattern for heat dissipation being connected to each other on the backside of the semiconductor substrate; and
solder balls disposed between the semiconductor devices, the solder balls transmitting heat having been transmitted to the metal pattern of the semiconductor device to the vias of the semiconductor device adjacent to a backside of the semiconductor device having the metal pattern.

2. A stacked semiconductor package, in which semiconductor devices each having a semiconductor element flip-chip mounted on a surface of a semiconductor substrate are stacked in a plurality of stages,
the semiconductor package comprising:
a metal pattern formed for heat dissipation on a backside of the semiconductor substrate, the metal pattern being in contact with the semiconductor element mounted on the semiconductor device adjacent to the backside;
vias formed on a periphery of the semiconductor substrate, the vias penetrating in a thickness direction to transmit heat, the vias and the metal pattern for heat dissipation being connected to each other on the backside of the semiconductor substrate; and
solder balls disposed between the semiconductor devices, the solder balls transmitting heat having been transmitted to the metal pattern of the semiconductor device to the vias of the semiconductor device adjacent to a backside of the semiconductor device having the metal pattern.

3. The stacked semiconductor package according to claim 1, wherein the metal pattern for heat dissipation on the backside of the semiconductor substrate of the semiconductor device and the semiconductor element mounted on the semiconductor device adjacent to the backside of the semiconductor device are bonded to each other with an adhesive having a high heat transfer coefficient.

4. The stacked semiconductor package according to claim 2, wherein the metal pattern for heat dissipation on the backside of the semiconductor substrate of the semiconductor device and the semiconductor element mounted on the semiconductor device adjacent to the backside of the semiconductor device are bonded to each other with an adhesive having a high heat transfer coefficient.

5. The stacked semiconductor package according to claim 1, wherein the metal pattern for heat dissipation is connected to the solder balls and vias used for ground electrodes.

6. The stacked semiconductor package according to claim 2, wherein the metal pattern for heat dissipation is connected to the solder balls and vias used for ground electrodes.

7. The stacked semiconductor package according to claim 1, wherein the semiconductor element has electrodes arranged in a lattice form over a surface of the semiconductor element.

8. The stacked semiconductor package according to claim 2, wherein the semiconductor element has electrodes arranged in a lattice form over a surface of the semiconductor element.
